(19) United States
(12) Patent Application Publication
(10) Pub. No.: US 2018/0261615 A1
(43) Pub. Date: Sep. 13, 2018

(54) SEMICONDUCTOR MEMORY DEVICE

(71) Applicant: Toshiba Memory Corporation, Minato-ku (JP)

(72) Inventor: Yoichi MINEMURA, Yokkaichi (JP)

(73) Assignee: Toshiba Memory Corporation, Minato-ku (JP)

(21) Appl. No.: 15/700,408

(22) Filed: Sep. 11, 2017

Related U.S. Application Data
(60) Provisional application No. 62/469,896, filed on Mar. 10, 2017.

(51) Int. Cl. H01L 27/11556; H01L 27/11519; H01L 27/11524

(52) U.S. Cl. CPC H01L 27/11556; H01L 27/11524; H01L 27/11519

(57) ABSTRACT

A semiconductor memory device includes a stacked body, a first semiconductor member, a first insulating layer, a second semiconductor member, and a second insulating layer. The stacked body includes an electrode film and an insulating film arranged alternately along a first direction. The first and second semiconductor members extend in the first direction and pierce the electrode film and the insulating film. The first insulating layer contacts the insulating film and is provided at a periphery of the first semiconductor member. The second insulating layer contacts the insulating film and is provided at a periphery of the second semiconductor member. The first insulating layer is thicker than the second insulating layer. A major diameter of the first semiconductor member is smaller than a major diameter of the second semiconductor member when viewed from the first direction.

### CROSS-REFERENCE TO RELATED APPLICATIONS

This application is based upon and claims the benefit of priority from U.S Provisional Patent Application 62/469,896, filed on Mar. 10, 2017; the entire contents of which are incorporated herein by reference.

### FIELD

Embodiments relate to a semiconductor memory device.

### BACKGROUND

In recent years, a stacked type semiconductor memory device has been proposed in which memory cells are integrated three-dimensionally. In such a stacked type semiconductor memory device, a stacked body in which electrode films and insulating films are stacked alternately is provided on a semiconductor substrate; and semiconductor pillars that pierce the stacked body are provided. Also, memory cells are formed at each crossing portion between the electrode films and the semiconductor pillars. Faster operations are a challenge in such a semiconductor memory device.

### BRIEF DESCRIPTION OF THE DRAWINGS

FIG. 1 is a perspective view showing a semiconductor memory device according to a first embodiment;

FIG. 2 and FIG. 3 are cross-sectional views showing the semiconductor memory device according to the first embodiment;

FIG. 4 to FIG. 6 are cross-sectional views showing a method for manufacturing a semiconductor memory device according to the first embodiment;

FIG. 7 is a cross-sectional view showing a semiconductor memory device according to a first modification of the first embodiment;

FIG. 8 is a cross-sectional view showing a semiconductor memory device according to a second modification of the first embodiment;

FIG. 9 is a cross-sectional view showing a semiconductor memory device according to a third modification of the first embodiment;

FIG. 10 is a cross-sectional view showing a semiconductor memory device according to a fourth modification of the first embodiment;

FIG. 11 is a cross-sectional view showing a semiconductor memory device according to a fifth modification of the first embodiment;

FIG. 12 and FIG. 13 are cross-sectional views showing a semiconductor memory device according to a second embodiment;

FIG. 14 to FIG. 16 are cross-sectional views showing a method for manufacturing a semiconductor memory device according to the second embodiment;

FIG. 17 is a cross-sectional view showing a semiconductor memory device according to a modification of the second embodiment;

FIG. 18 is a cross-sectional view showing a semiconductor memory device according to a third embodiment; and

FIG. 19 is a perspective view showing a semiconductor memory device according to a fourth embodiment.

### DETAILED DESCRIPTION

A semiconductor memory device according to an embodiment, includes a stacked body, a first semiconductor member, a first charge storage layer, a first insulating layer, a second semiconductor member, a second charge storage layer, and a second insulating layer. The stacked body includes an electrode film and an insulating film arranged alternately along a first direction. The first semiconductor member extends in the first direction and pierces the electrode film and the insulating film. The first charge storage layer is provided at a periphery of the first semiconductor member. The first insulating layer contacts the insulating film and is provided at a periphery of the first charge storage layer. The second semiconductor member extends in the first direction and pierces the electrode film and the insulating film. The second charge storage layer is provided at a periphery of the second semiconductor member. The second insulating layer contacts the insulating film and is provided at a periphery of the second charge storage layer. The first insulating layer is thicker than the second insulating layer. A major diameter of the first semiconductor member is smaller than a major diameter of the second semiconductor member when viewed from the first direction.

### First Embodiment

First, a first embodiment will be described.

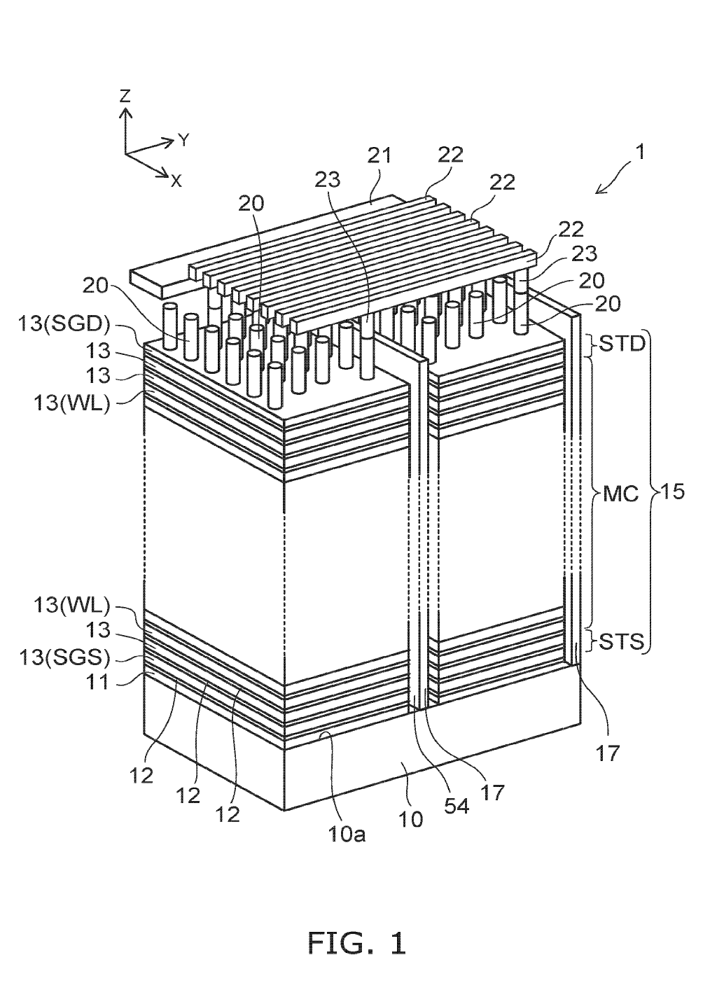

FIG. 1 is a perspective view showing a semiconductor memory device according to the embodiment.

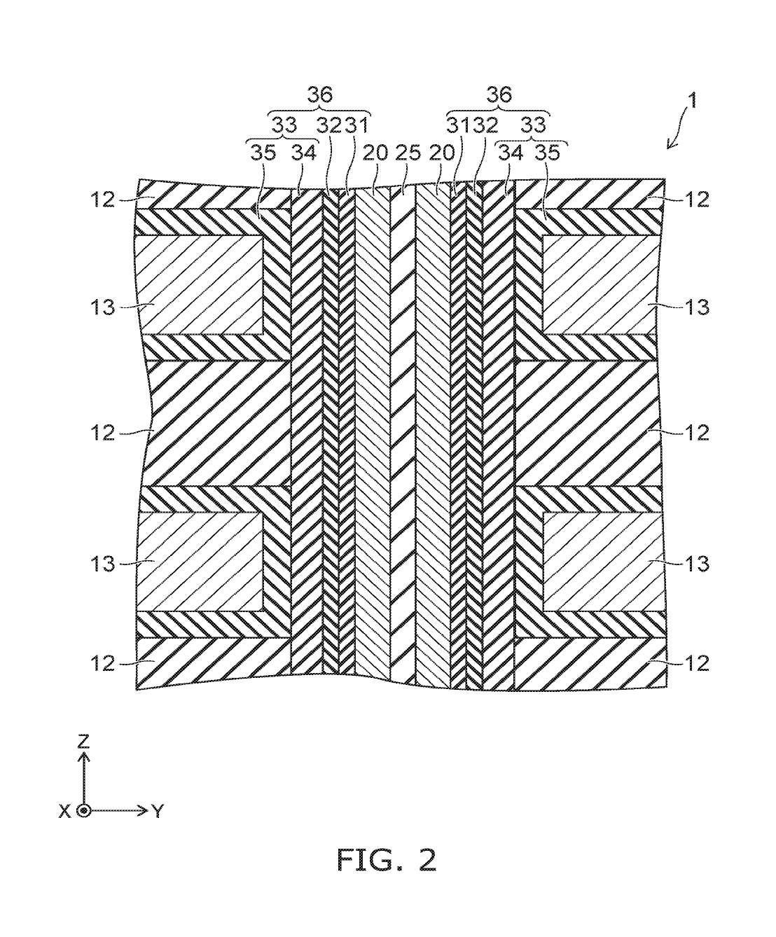

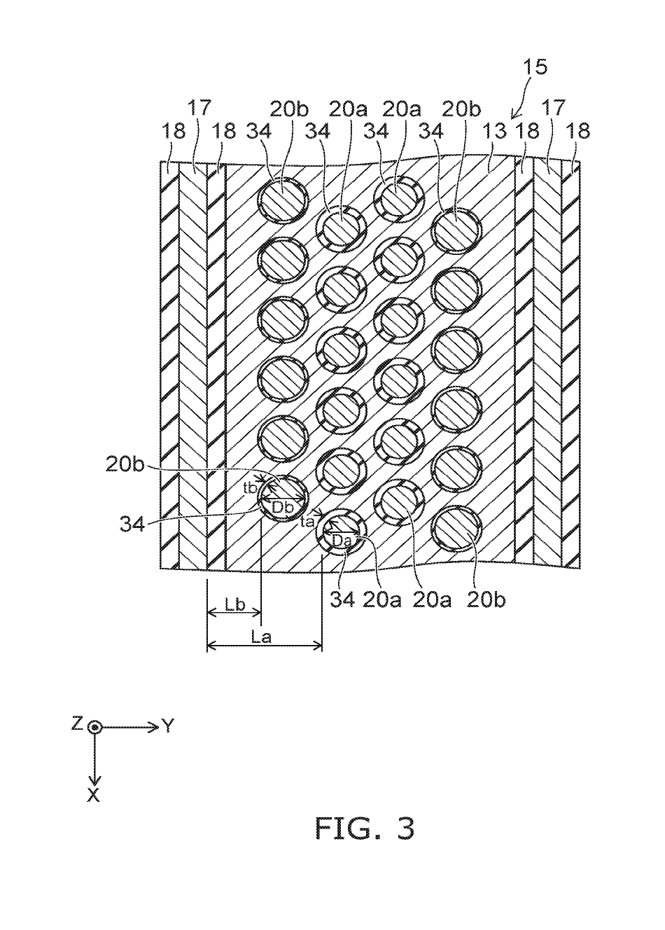

FIG. 2 and FIG. 3 are cross-sectional views showing the semiconductor memory device according to the embodiment.

The drawings are schematic and are drawn with appropriate exaggerations. For example, the components are drawn to be larger and fewer than the actual components. This is similar for the other drawings described below as well.

The semiconductor memory device according to the embodiment is stacked NAND flash memory.

As shown in FIG. 1, a silicon substrate 10 is provided in the semiconductor memory device 1 according to the embodiment (hereinbelow, also called simply the “device 1”). The silicon substrate 10 is formed of, for example, a monocrystal of silicon. A silicon oxide film 11 is provided on the silicon substrate 10.

An XYZ orthogonal coordinate system is employed for convenience of description in the specification hereinbelow. Two mutually-orthogonal directions parallel to an upper surface 10a of the silicon substrate 10 are taken as an “X-direction” and a “Y-direction;” and a direction perpendicular to the upper surface 10a of the silicon substrate 10 is taken as a “Z-direction.” Also, although a direction that is in the Z-direction from the silicon substrate 10 toward the silicon oxide film 11 also is called “up” and the reverse direction also is called “down,” these expressions are for convenience and are independent of the direction of gravity.

Also, in the specification, “silicon oxide film” refers to a film having silicon oxide (SiO) as a major component and includes silicon (Si) and oxygen (O). This is similar for the other components as well; and in the case where the material name is included in the name of the component, the material is a major component of the component. Also, because silicon oxide generally is an insulating material, a silicon oxide film is an insulating film unless otherwise indicated. This is similar for the other members as well; and as a general rule, the characteristics of the member reflect the characteristics of the major component.

Silicon oxide films 12 and electrode films 13 are stacked alternately along the Z-direction on the silicon oxide film 11. The stacked body 15 is formed of the silicon oxide film 11 and of the multiple silicon oxide films 12 and the multiple electrode films 13 that are stacked alternately. The longitudinal direction of the stacked body 15 is the X-direction. Source electrode plates 17 are provided at positions so that the stacked body 15 is interposed between the positions in the Y-direction. The configuration of the source electrode plate 17 is a plate configuration; the longest longitudinal direction of the source electrode plate 17 is the X-direction; the next longest width direction is the Z-direction; and the shortest thickness direction is the Y-direction. The lower end of the source electrode plate 17 is connected to the silicon substrate 10.

In the device 1, the multiple stacked bodies 15 and the multiple source electrode plates 17 are provided and arranged alternately along the Y-direction. An insulating plate 18 (referring to FIG. 3) that is made of, for example, silicon oxide is provided between the stacked body 15 and the source electrode plate 17.

A silicon pillar 20 that extends in the Z-direction and pierces the stacked body 15 is provided inside the stacked body 15. The silicon pillar 20 is made of polysilicon; and the configuration of the silicon pillar 20 is a circular tube having a plugged lower end portion. The lower end of the silicon pillar 20 is connected to the silicon substrate 10; and the upper end is exposed at the upper surface of the stacked body 15. The configurations of the silicon pillar 20 and the periphery of the silicon pillar 20 are described below.

Multiple bit lines 22 and a source line 21 that extend in the Y-direction are provided on the stacked body 15. The bit lines 22 are provided higher than the source line 21. The source line 21 is connected to the upper end of the source electrode plate 17 via a plug (not illustrated). Also, the bit line 22 is connected to the upper end of the silicon pillar 20 via a plug 23. Thereby, the current path of (bit line 22-plug 23-silicon pillar 20-silicon substrate 10-source electrode plate 17-source line 21) is formed; and each of the silicon pillars 20 is connected between the bit line 22 and the silicon substrate 10.

In the stacked body 15, the electrode films 13 of one or multiple levels from the top function as upper selection gate lines SGD; and upper selection gate transistors STD are configured at each crossing portion between the upper selection gate lines SGD and the silicon pillars 20. Also, the electrode films 13 of one or multiple levels from the bottom function as lower selection gate lines SGS; and a lower selection gate transistor STS is configured at each crossing portion between the lower selection gate lines SGS and the silicon pillars 20. The electrode films 13 other than the lower selection gate lines SGS and the upper selection gate lines SGD function as word lines WL; and a memory cell transistor MC is configured at each crossing portion between the word lines WL and the silicon pillars 20. Thereby, a NAND string is formed by the multiple memory cell transistors MC being connected in series along each of the silicon pillars 20, and by the lower selection gate transistor STS and the upper selection gate transistor STD being connected at the two ends of the multiple memory cell transistors MC.

As shown in FIG. 2, a core member 25 that is made of silicon oxide is provided inside the silicon pillar 20. A tunneling insulating film 31, a charge storage film 32, and a blocking insulating film 33 are provided between the silicon pillar 20 and the electrode film 13 in this order from the silicon pillar 20 toward the electrode film 13. The blocking insulating film 33 includes a silicon oxide layer 34 and an aluminum oxide layer 35. The dielectric constant of the aluminum oxide layer 35 is higher than the dielectric constant of the silicon oxide layer 34. A memory film 36 is formed of the tunneling insulating film 31, the charge storage film 32, and the blocking insulating film 33. The memory film 36 is disposed between the silicon pillar 20 and the electrode film 13.

Although the tunneling insulating film 31 normally is insulative, the tunneling insulating film 31 is a film in which a tunneling current flows when a prescribed voltage within the range of the drive voltage of the device 1 is applied and is, for example, a single-layer silicon oxide film, or an ONO film in which a silicon oxide layer, a silicon nitride layer, and a silicon oxide layer are stacked in this order. The charge storage film 32 is a film that can store charge, is made from, for example, a material having trap sites of electrons, and is made of, for example, silicon nitride (SiN). The blocking insulating film 33 is a film in which a current substantially does not flow even when a voltage within the range of the drive voltage of the device 1 is applied. The tunneling insulating film 31, the charge storage film 32, and the silicon oxide layer 34 are disposed on substantially the entire side surface of the silicon pillar 20; and the configurations of the tunneling insulating film 31, the charge storage film 32, and the silicon oxide layer 34 are circular tubes. The aluminum oxide layer 35 is formed on the upper surface of the electrode film 13, on the lower surface of the electrode film 13, and on the side surface of the electrode film 13 facing the silicon pillar 20. The silicon oxide layer 34 contacts the silicon oxide films 12.

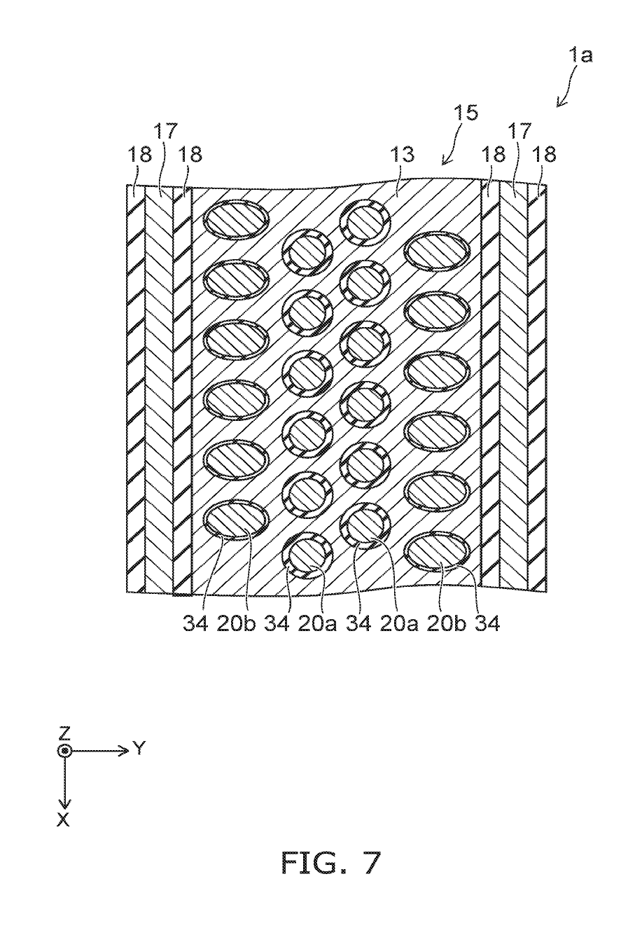

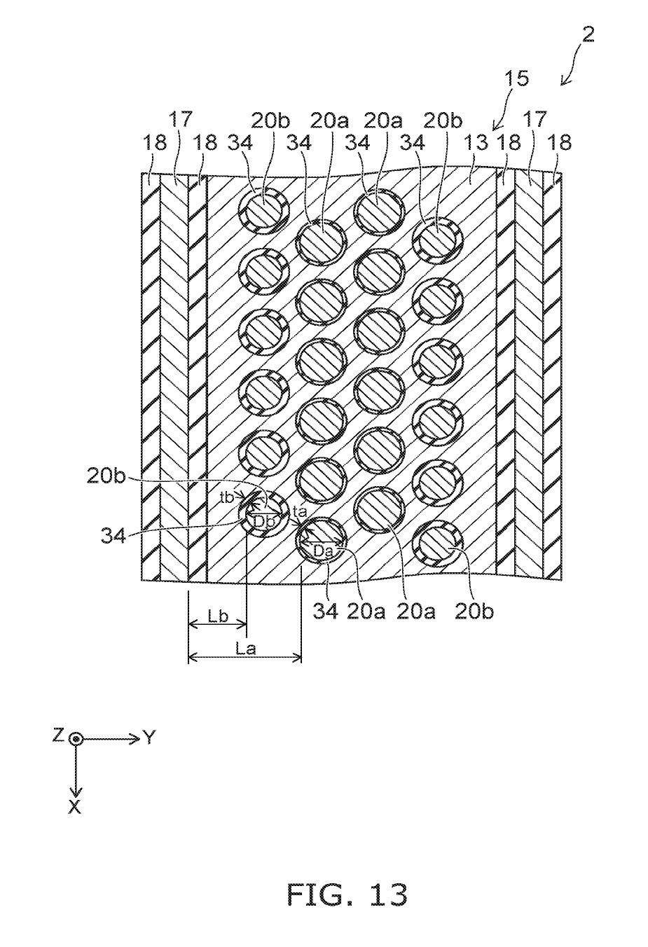

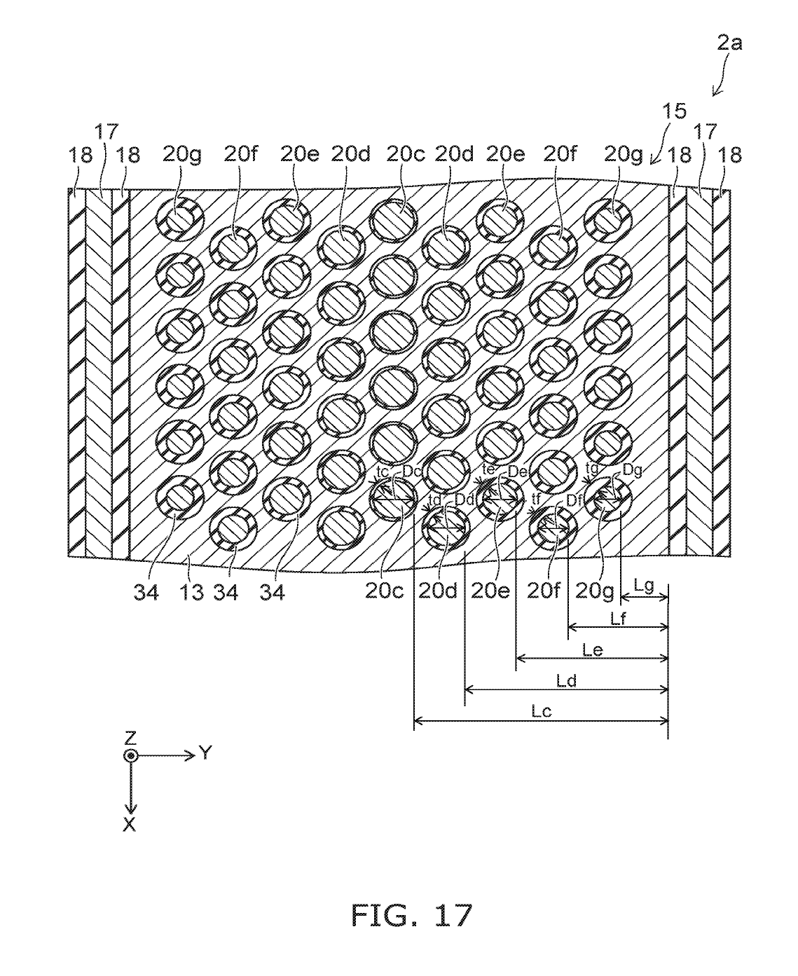

As shown in FIG. 3, the silicon pillars 20 are arranged periodically along multiple columns, e.g., four columns, when viewed from the Z-direction. Each of the columns extends in the X-direction; and the positions of the silicon pillars 20 in the X-direction are shifted half a period between the mutually-adjacent columns. FIG. 3 shows an XY cross section at any position in the Z-direction. Also, in FIG. 3, the core member 25, the tunneling insulating film 31, the charge storage film 32, and the aluminum oxide layer 35 are not illustrated for easier viewing of the drawing. This is similar for FIG. 7 to FIG. 11, FIG. 13, and FIG. 17 described below as well.

Among the silicon pillars 20 of the four columns provided inside the stacked body 15, the silicon pillars 20 of the two columns disposed at the central portion in the width direction, i.e., the Y-direction, of the stacked body 15 are called “silicon pillars 20a;” and the silicon pillars 20 of the two columns disposed at the two Y-direction end portions of the stacked body 15 are called “silicon pillars 20b.” A distance La between the silicon pillar 20a and the source electrode plate 17 proximal to the silicon pillar 20a is longer than a distance Lb between the silicon pillar 20b and the source electrode plate 17 proximal to the silicon pillar 20b. In other words, La>Lb.

Also, when viewed from the Z-direction, the shape of the silicon pillar 20a is substantially a circle; and a major diameter Da of the silicon pillar 20a is smaller than a major diameter Db of the silicon pillar 20b. In other words, Da<Db. If the shape of the silicon pillar 20a when viewed from the Z-direction is a perfect circle, the major diameter has the same meaning as the diameter.

Also, a thickness to of the silicon oxide layer 34 provided at the periphery of the silicon pillar 20a is thicker than a thickness tb of the silicon oxide layer 34 provided at the periphery of the silicon pillar 20b. In other words, ta>tb.

A method for manufacturing the semiconductor memory device according to the embodiment will now be described.

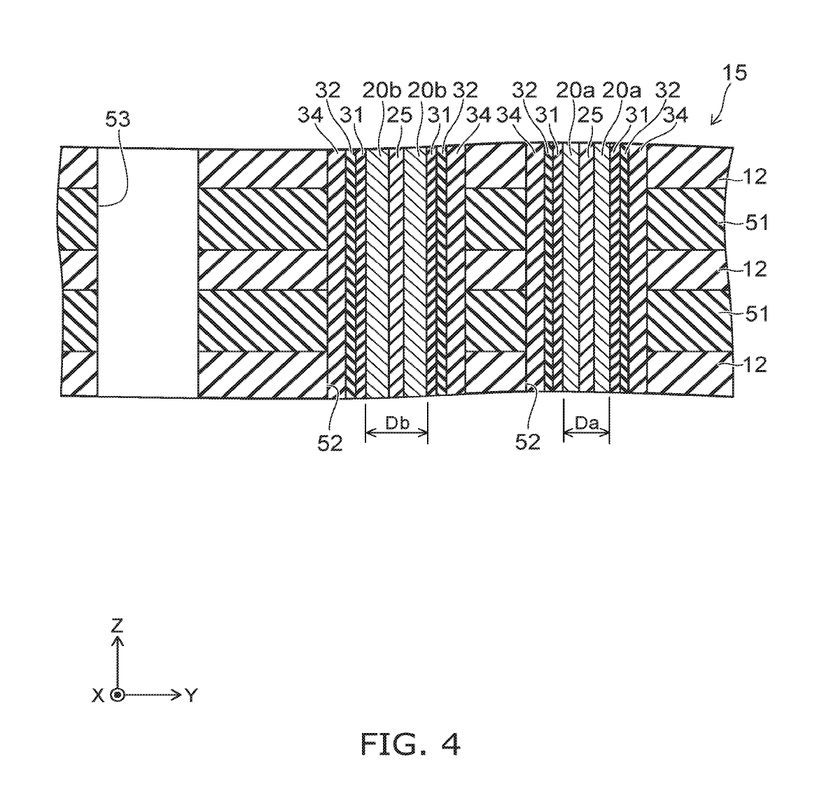

FIG. 4 to FIG. 6 are cross-sectional views showing the method for manufacturing the semiconductor memory device according to the embodiment.

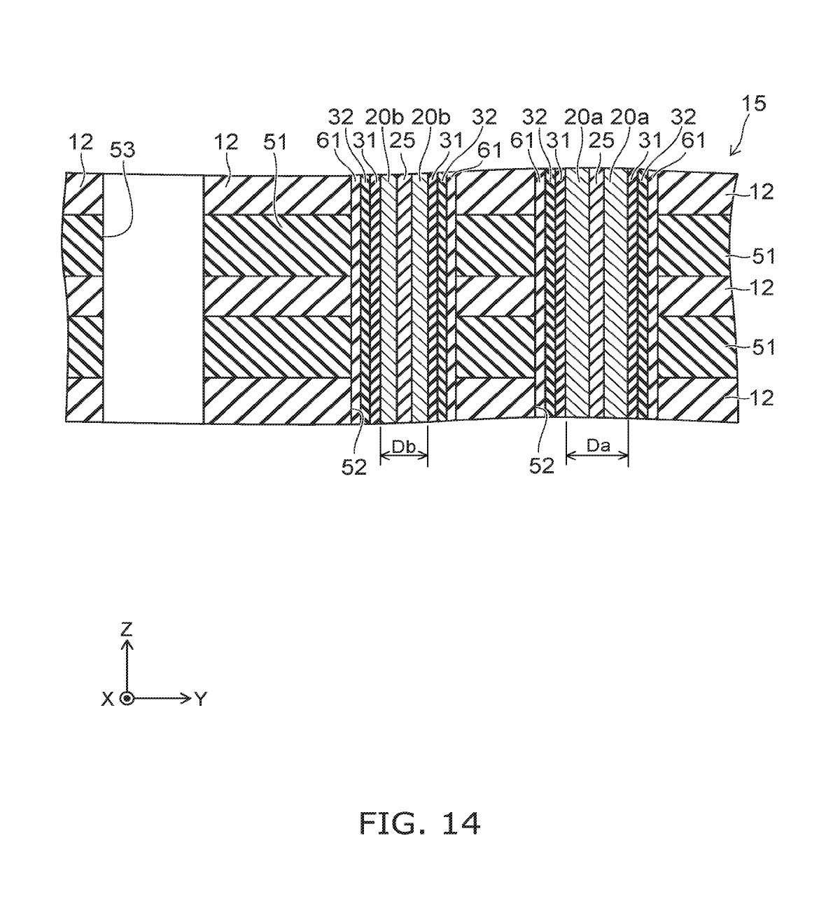

Although the central axes of two holes 52 are drawn as being positioned on the same YZ cross section for convenience of description in FIG. 4 to FIG. 6, actually, the positions in the X-direction of these holes 52 are different from each other as shown in FIG. 3. This is similar for FIG. 14 to FIG. 16 described below as well.

First, as shown in FIG. 1, the silicon oxide film 11 is formed on the silicon substrate 10.

Then, as shown in FIG. 4, the stacked body 15 is formed by alternately stacking silicon nitride films 51 and the silicon oxide films 12. Then, the holes 52 that extend in the Z-direction are formed in the stacked body 15 and caused to reach the silicon substrate 10 by, for example, anisotropic etching such as RIE (Reactive Ion Etching), etc. At this time, the major diameters of the holes 52 are adjusted according to the positions where the holes 52 are formed so that the major diameter Da of the silicon pillar 20a becomes smaller than the major diameter Db of the silicon pillar 20b in a subsequent process.

Then, the silicon oxide layer 34, the charge storage film 32, the tunneling insulating film 31, the silicon pillar 20, and the core member 25 are formed inside the holes 52. At this time, the silicon pillar 20 is connected to the silicon substrate 10. Also, the major diameter Da of the silicon pillar 20a is smaller than the major diameter Db of the silicon pillar 20b. Then, slits 53 that extend in the X-direction are multiply formed in the stacked body 15. The slits 53 pierce the stacked body 15 and reach the silicon substrate 10.

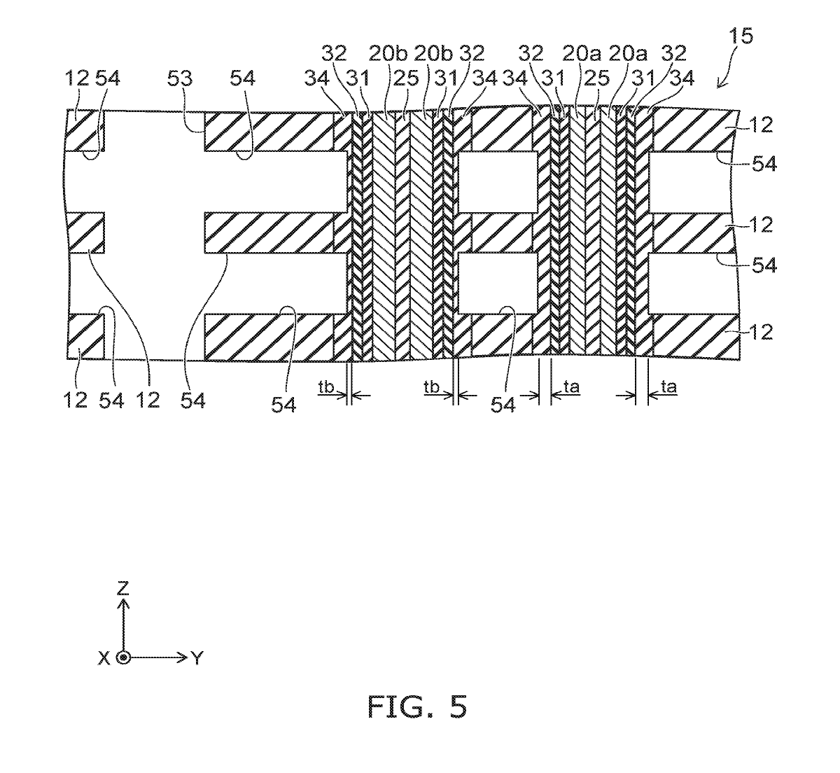

Then, as shown in FIG. 5, isotropic etching of the stacked body 15 is performed. The conditions of the isotropic etching are set to conditions such that the etching rate of silicon nitride is higher than the etching rate of silicon oxide. For example, wet etching using hot phosphoric acid is performed. Thereby, the silicon nitride films 51 (referring to FIG. 4) are removed via the slits 53; and spaces 54 are formed. The silicon oxide layer 34 is exposed at the inner surfaces of the spaces 54.

At this time, a portion of the silicon oxide layer 34 exposed inside the spaces 54 also is etched somewhat. Compared to the silicon oxide layer 34 disposed at a position distal to the slit 53, the silicon oxide layer 34 that is disposed at a position proximal to the slit 53 is etched more by being exposed to the etching for a longer time; and the thickness after the etching is thin. As a result, the thickness tb of the silicon oxide layer 34 disposed between the silicon pillar 20b and the space 54 is thinner than the thickness to of the silicon oxide layer 34 disposed between the silicon pillar 20a and the space 54.

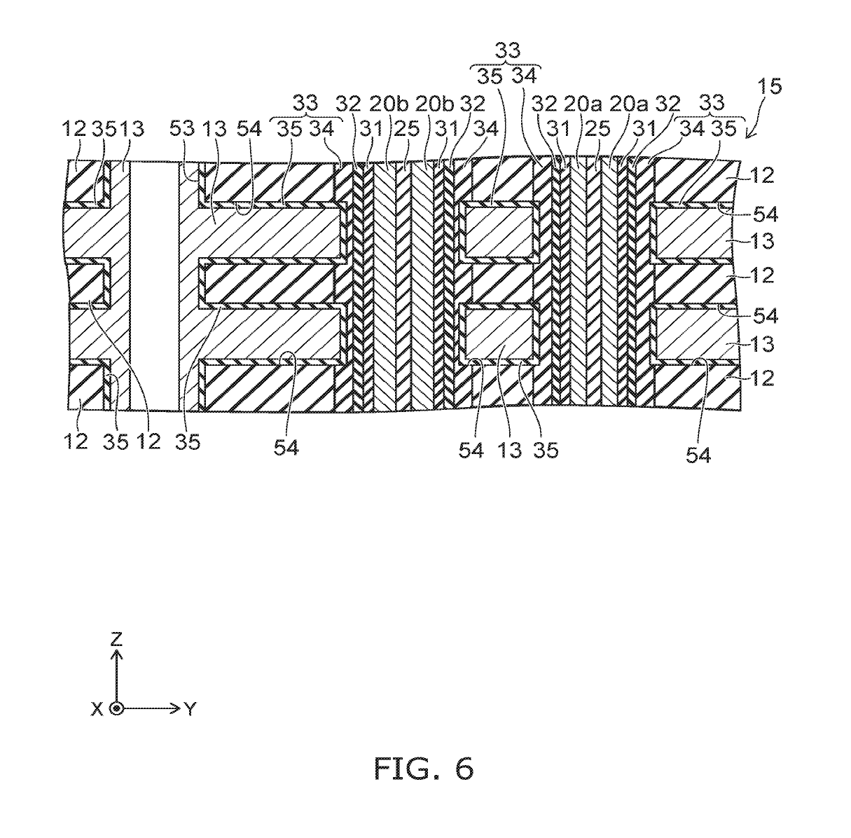

Then, as shown in FIG. 6, the aluminum oxide layer 35 is formed on the inner surface of the slit 53 and on the inner surfaces of the spaces 54. Then, a barrier metal layer (not illustrated) that is made of, for example, titanium (Ti), titanium nitride (TiN), etc., is formed on the surface of the aluminum oxide layer 35. Then, the electrode film 13 is formed by depositing tungsten (W). At this time, the interiors of the spaces 54 are filled with the electrode film 13. Then, the portions of the electrode film 13, the barrier metal layer, and the aluminum oxide layer 35 deposited inside the slit 53 are removed by performing etching such as RIE, etc. Then, the insulating plate 18 (referring to FIG. 3) is formed on the inner side surface of the slit 53.

Then, as shown in FIG. 1, the source electrode plates 17 are filled into the slits 53 and connected to the silicon substrate 10. Then, the plugs 23, the source lines 21, the bit lines 22, etc., are formed on the stacked body 15. Thus, the semiconductor memory device 1 according to the embodiment is manufactured.

Operations of the semiconductor memory device according to the embodiment will now be described.

A control circuit (not illustrated) applies an ON potential to a lower selection gate electrode LSG and an upper selection gate electrode USG of the NAND string including the memory cell transistor MC to be programmed to set a lower selection transistor LST and an upper selection transistor UST to the ON state. Then, for example, the potential of the silicon pillar 20 is set to the ground potential by applying a ground potential GVD to the source line 21 and the bit line 22. On the other hand, a positive programming potential is applied to the selected word line WL; and the ON potential is applied to the unselected word lines WL. The programming potential is higher than the ON potential. Thereby, in the memory cell transistor MC to be programmed, electrons that are inside the silicon pillar 20 are injected into the charge storage film 32 via the tunneling insulating film 31. The threshold of the memory cell transistor MC changes when the electrons are injected into the charge storage film 32. Thereby, data is programmed to the memory cell transistor MC.

Effects of the embodiment will now be described.

In the embodiment, the silicon oxide layers 34 are unavoidably etched when removing the silicon nitride films 51 (referring to FIG. 4) in the process shown in FIG. 5. At this time, the silicon oxide layers 34 that are more proximal to the slit 53 are etched more because the silicon oxide layers 34 proximal to the slit 53 are exposed to the etching for a long period of time. As a result, as shown in FIG. 3, the silicon oxide layers 34 that surround the silicon pillars 20b positioned at the two Y-direction end portions of the stacked body 15 become thinner than the silicon oxide layers 34 surrounding the silicon pillars 20a positioned at the Y-direction central portion of the stacked body 15.

If the silicon oxide layer 34 is thin, the blocking insulating film 33 becomes thin; and the electric field of the electrode film 13 acting on the silicon pillar 20 becomes strong. Therefore, for example, in the program operation, the electrons are not injected easily into the charge storage film 32 due to the thick blocking insulating film 33 for the memory cell transistors MC proximal to the Y-direction central portion of the stacked body 15, even when the programming potential is applied to the electrode film 13. Thereby, the threshold of the memory cell transistor MC undesirably fluctuates after the program operation. To compensate this fluctuation, it is necessary to repeat the application of the programming potential and the verification over and over again; but by doing so, the operation speed of the semiconductor memory device 1 undesirably decreases.

Therefore, in the embodiment as shown in FIG. 3, the major diameters Da of the silicon pillars 20a positioned at the Y-direction central portion of the stacked body 15 are set to be smaller than the major diameters Db of the silicon pillars 20b positioned at the two Y-direction end portions. As the major diameter of the silicon pillar 20 is set to be smaller, the curvature of the surface of the electrode film 13 opposing the silicon pillar 20 becomes large; and the electric field of the electrode film 13 acting on the silicon pillar 20 becomes strong. Therefore, the electrons are injected more easily into the charge storage film 32 for the memory cell transistors MC having smaller major diameters of the silicon pillars 20.

Thus, according to the embodiment, the effect due to the major diameter of the silicon pillar 20 can cancel the effect due to the thickness of the silicon oxide layer 34. Therefore, the fluctuation of the threshold of the program operation is small; the step-up width of the programming potential can be increased; and the number of repetitions of the application of the programming potential and the verification can be reduced. Accordingly, the operation speed of the semiconductor memory device 1 is high.

### First Modification of First Embodiment

A first modification of the first embodiment will now be described.

FIG. 7 is a cross-sectional view showing a semiconductor memory device according to the modification.

In the semiconductor memory device la according to the modification as shown in FIG. 7, the shapes of the silicon pillars 20b disposed at the two Y-direction end portions of the stacked body 15 are ellipses when viewed from the Z-direction. For example, the major diameter of the ellipse extends in the Y-direction. In the specification, “ellipse” is not limited to a mathematically rigorous ellipse, refers generally to a shape in which a circle is elongated in one direction, and includes, for example, an oval.

According to the modification, the major diameters of the silicon pillar 20a and the silicon pillar 20b are set to be different by setting the cross-sectional shapes to be different. Thereby, the fluctuation of the cross-sectional area between the silicon pillar 20a and the silicon pillar 20b can be suppressed.

Otherwise, the configuration, the manufacturing method, the operations, and the effects of the modification are similar to those of the first embodiment described above.

### Second Modification of First Embodiment

A second modification of the first embodiment will now be described.

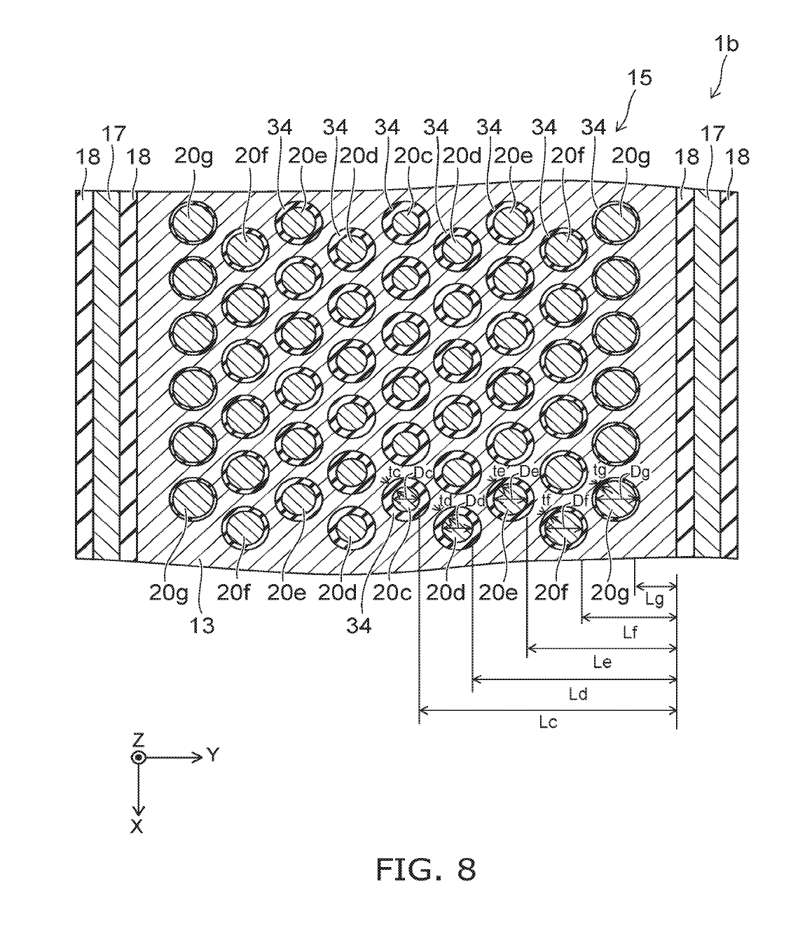

FIG. 8 is a cross-sectional view showing a semiconductor memory device according to the modification.

In the semiconductor memory device 1b according to the modification as shown in FIG. 8, nine columns of the silicon pillars 20 are arranged along the Y-direction in the stacked body 15. Each of the columns of the silicon pillars 20 extends in the X-direction.

Among the nine columns of the silicon pillars 20 provided inside the stacked body 15, the silicon oxide layer 34 is thinner and the major diameter is larger when viewed from the Z-direction for the silicon pillars 20 more proximal to the source electrode plate 17. In other words, as shown in FIG. 8, when the silicon pillars 20 piercing the stacked body 15 are classified as silicon pillars 20c, 20d, 20e, 20f, and 20g from the Y-direction central column toward the column at the Y-direction end portion of the stacked body 15, the distances between the silicon pillars 20 and the source electrode plate 17 proximal to each silicon pillar 20 respectively are Lc, Ld, Le, Lf, and Lg; the major diameters when viewed from the Z-direction respectively are Dc, Dd, De, Df, and Dg; and the thicknesses of the silicon oxide layer 34 surrounding each silicon pillar 20 respectively are tc, td, te, and tf. In such a case, if Lc>Ld>Le>Lf>Lg, then Dc<Dd<De<Df<Dg; and tc>td>te>tf>tg.

According to the modification, even in the case where nine columns of the silicon pillars 20 are arranged in the stacked body 15, effects similar to those of the first embodiment described above can be obtained.

Otherwise, the configuration, the manufacturing method, the operations, and the effects of the modification are similar to those of the first embodiment described above.

The silicon pillars 20c that belong to the Y-direction central column may be dummy pillars, i.e., silicon pillars that are not included in the memory cell transistors MC. In such a case, the shape and major diameter of the silicon pillars 20c may not satisfy the relationship described above.

### Third Modification of First Embodiment

A third modification of the first embodiment will now be described.

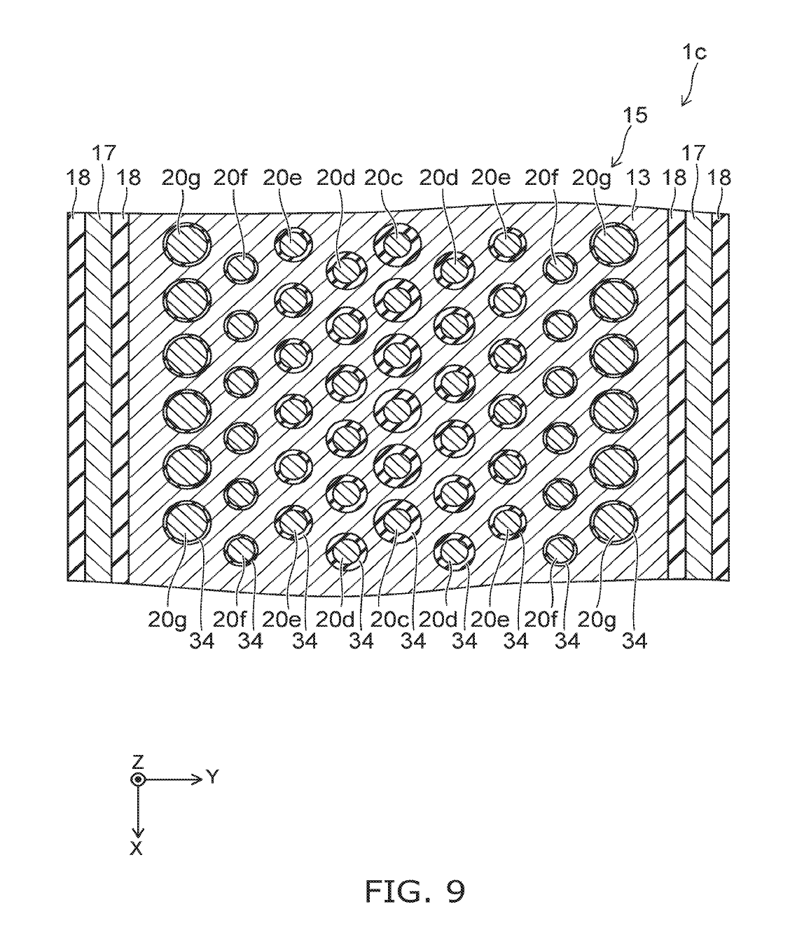

FIG. 9 is a cross-sectional view showing a semiconductor memory device according to the modification.

In the semiconductor memory device 1c according to the modification as shown in FIG. 9, the major diameters of the silicon pillars 20g belonging to the outermost column of the stacked body 15 are larger than the major diameters of the silicon pillars 20c to 20f belonging to the other columns. Also, the major diameters of the silicon pillars 20c to 20f are substantially equal to each other.

According to the modification, the effect of the silicon oxide layer 34 becoming thin for the silicon pillars 20g belonging to the outermost column of the stacked body 15 can be compensated by setting the major diameters of the silicon pillars 20 to be large.

Otherwise, the configuration, the manufacturing method, the operations, and the effects of the modification are similar to those of the first embodiment described above.

### Fourth Modification of First Embodiment

A fourth modification of the first embodiment will now be described.

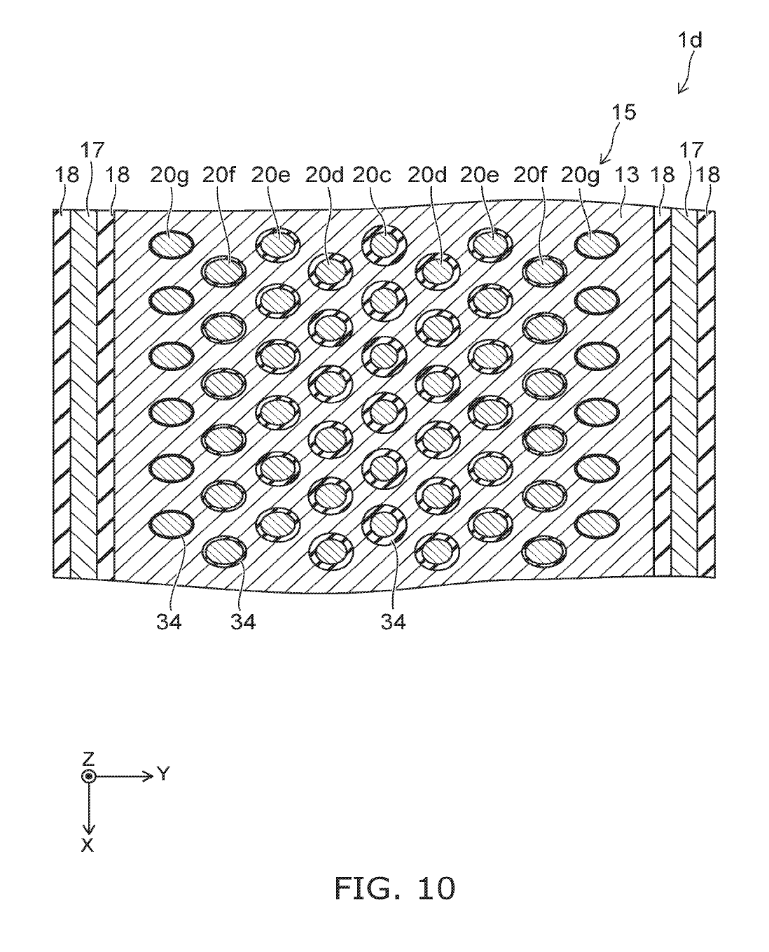

FIG. 10 is a cross-sectional view showing a semiconductor memory device according to the modification.

As shown in FIG. 10, the modification is an example in which the first modification and the second modification described above are combined. In other words, in the semiconductor memory device 1d according to the modification, the cross-sectional shapes of the silicon pillars 20c positioned at the Y-direction central portion of the stacked body 15 are circles; for the other silicon pillars 20d to 20g, the cross-sectional shapes are ellipses; and the ellipse eccentricities are larger for the silicon pillars 20 more proximal to the source electrode plate 17.

Otherwise, the configuration, the manufacturing method, the operations, and the effects of the modification are similar to those of the first modification and the second modification described above.

### Fifth Modification of First Embodiment

A fifth modification of the first embodiment will now be described.

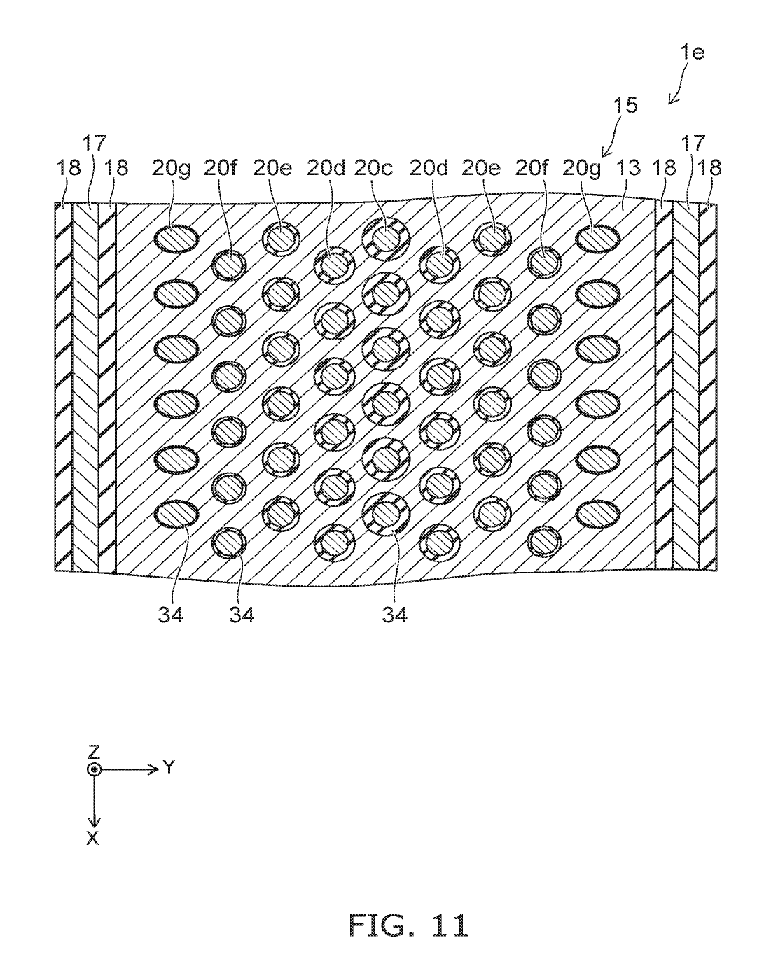

FIG. 11 is a cross-sectional view showing a semiconductor memory device according to the modification.

As shown in FIG. 11, the modification is an example in which the first to third modifications described above are combined. In other words, in the semiconductor memory device 1e according to the modification, nine columns of the silicon pillars 20 are arranged in the stacked body 15; the cross-sectional shapes of the silicon pillars 20g belonging to the outermost column of the stacked body 15 are ellipses; and the cross-sectional shapes of the silicon pillars 20a to 20d belonging to the other columns are circles.

According to the modification as well, the effect of the silicon oxide layer 34 becoming thinner toward the end portion of the stacked body 15 is canceled by setting the major diameters of the silicon pillars 20 to be larger toward the end portion of the stacked body 15.

Otherwise, the configuration, the manufacturing method, the operations, and the effects of the modification are similar to those of the first to third modifications described above.

### Second Embodiment

A second embodiment will now be described.

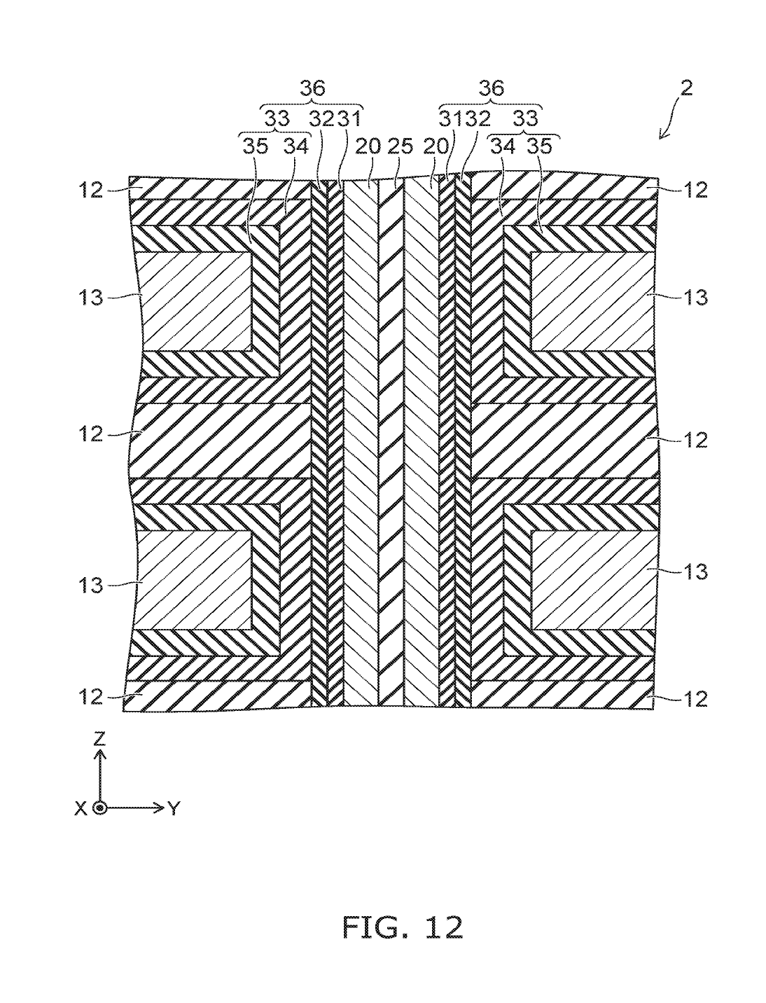

FIG. 12 and FIG. 13 are cross-sectional views showing a semiconductor memory device according to the embodiment.

As shown in FIG. 12, compared to the semiconductor memory device 1 according to the first embodiment described above (referring to FIG. 2), the configuration and arrangement of the silicon oxide layer 34 are different in the semiconductor memory device 2 according to the embodiment. Specifically, the configuration of the silicon oxide layer 34 is not a tubular configuration surrounding the silicon pillar 20 but is a configuration covering the electrode film 13. The silicon oxide layer 34 is provided on the upper surface of the aluminum oxide layer 35, on the lower surface of the aluminum oxide layer 35, and on the side surface of the aluminum oxide layer 35 facing the silicon pillar 20. In other words, the entire silicon oxide layer 34 is stacked with the aluminum oxide layer 35. The silicon oxide layer 34 contacts the silicon oxide films 12.

In the semiconductor memory device 2 according to the embodiment as shown in FIG. 13, contrary to the semiconductor memory device 1 according to the first embodiment described above (referring to FIG. 3), the major diameters Da of the silicon pillars 20a of the two columns disposed at the Y-direction central portion of the stacked body 15 are larger than the major diameters Db of the silicon pillars 20b of the two columns disposed at the two Y-direction end portions of the stacked body 15. Also, the thickness ta of the silicon oxide layer 34 provided at the periphery of the silicon pillar 20a is thinner than the thickness tb of the silicon oxide layer 34 provided at the periphery of the silicon pillar 20b. In other words, Da>Db and ta<tb when La>Lb.

A method for manufacturing the semiconductor memory device according to the embodiment will now be described.

FIG. 14 to FIG. 16 are cross-sectional views showing the method for manufacturing the semiconductor memory device according to the embodiment.

First, as shown in FIG. 14, the silicon oxide film 11 (referring to FIG. 1) is formed on the silicon substrate 10 (referring to FIG. 1); and the stacked body 15 is formed on the silicon oxide film 11 by alternately stacking the silicon nitride films 51 and the silicon oxide films 12. Then, the holes 52 that extend in the Z-direction are formed in the stacked body 15 and caused to reach the silicon substrate 10 by performing, for example, anisotropic etching such as RIE, etc. At this time, the major diameters of the holes 52 are adjusted according to the positions where the holes 52 are formed so that the major diameter Da of the silicon pillar 20a becomes larger than the major diameter Db of the silicon pillar 20b in a subsequent process.

Then, a dummy silicon oxide layer 61 is formed on the inner surfaces of the holes 52 by depositing silicon oxide. Then, the charge storage film 32, the tunneling insulating film 31, the silicon pillar 20, and the core member 25 are formed in this order on the side surface of the dummy silicon oxide layer 61. At this time, the silicon pillar 20 is connected to the silicon substrate 10. Also, the major diameter Da of the silicon pillar 20a is larger than the major diameter Db of the silicon pillar 20b. Then, the slits 53 that extend in the X-direction are multiply formed in the stacked body 15.

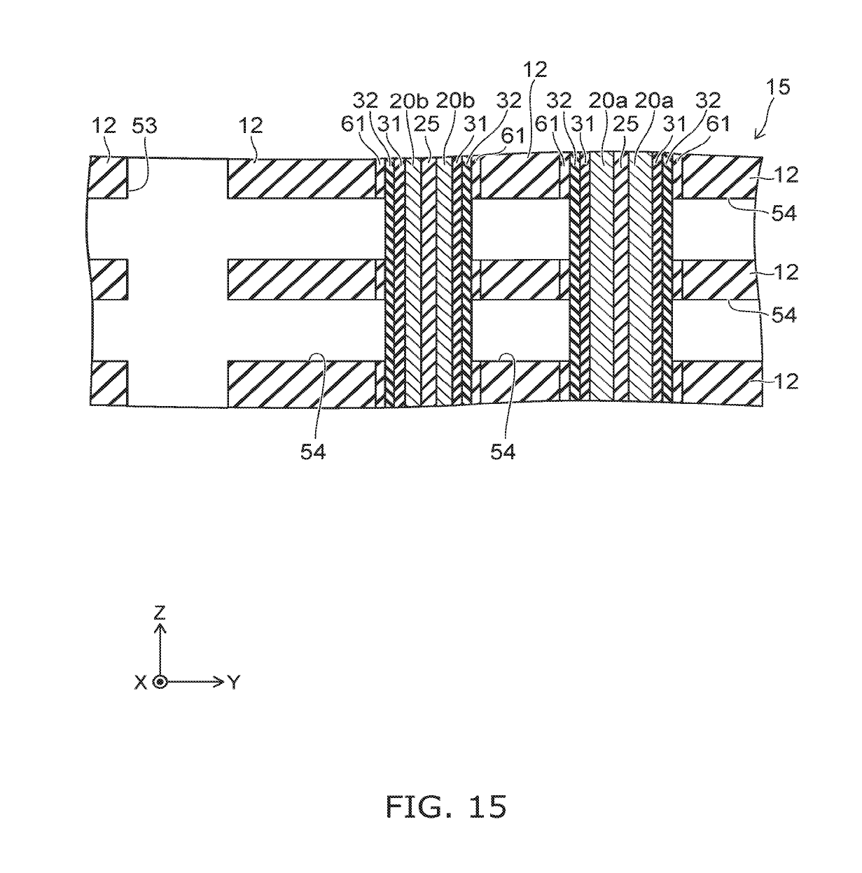

Then, as shown in FIG. 15, the spaces 54 are formed by removing the silicon nitride films 51 (referring to FIG. 14) via the slits 53 by performing, for example, wet etching using hot phosphoric acid. Then, the dummy silicon oxide layer 61 is removed from the back surfaces of the spaces 54 via the slits 53 and the spaces 54 by performing, for example, wet etching using BHF (buffered hydrofluoric acid).

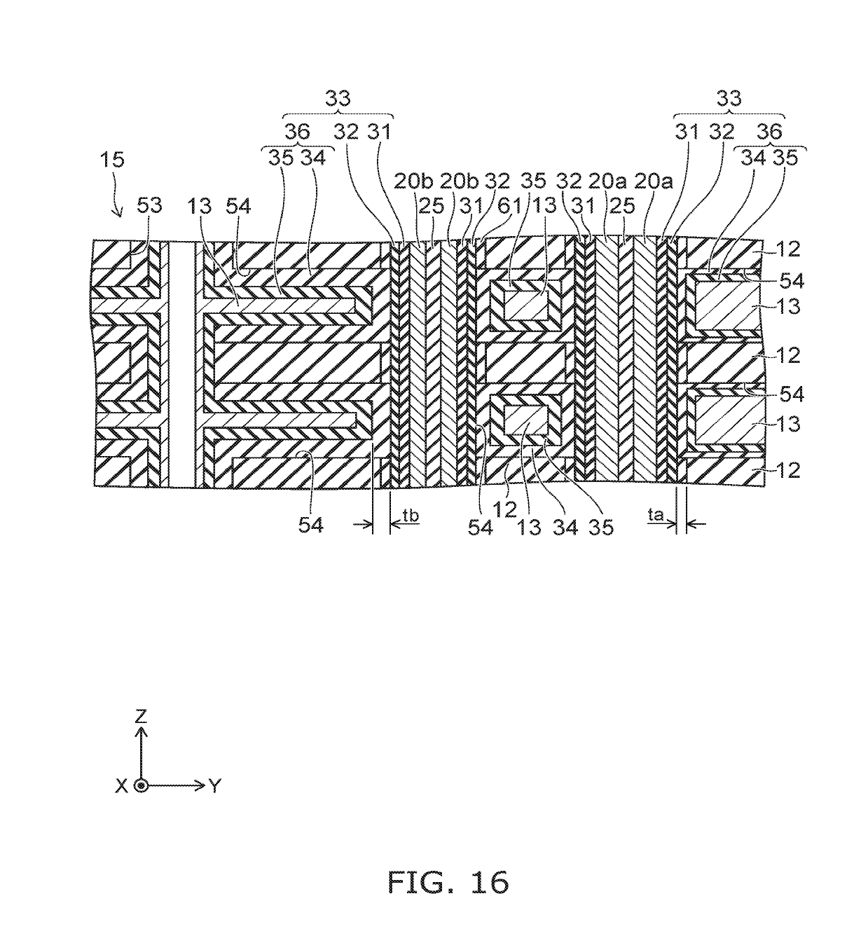

Then, as shown in FIG. 16, the silicon oxide layer 34 is formed on the inner surfaces of the slits 53 and on the inner surfaces of the spaces 54 by depositing silicon oxide. At this time, the thickness tb of the silicon oxide layer 34 disposed at the positions proximal to the slit 53 is thicker than the thickness to of the silicon oxide layer 34 disposed at the positions distal to the slit 53 because the silicon oxide is deposited more easily proximal to the slit 53.

Then, the aluminum oxide layer 35 is formed on the surface of the silicon oxide layer 34. Then, a barrier metal layer (not illustrated) is formed. Then, the electrode film 13 is formed by depositing tungsten (W) on the inner surfaces of the slits 53 and in the entire interiors of the spaces 54. Then, the portions of the electrode film 13, the barrier metal layer, the aluminum oxide layer 35, and the silicon oxide layer 34 deposited inside the slits 53 are removed by performing etching such as RIE, etc. Then, the insulating plate 18 (referring to FIG. 13) is formed on the inner side surfaces of the slits 53.

Then, the source electrode plate 17 (referring to FIG. 13) is filled into the slits 53 and connected to the silicon substrate 10 (referring to FIG. 1). The remainder of the dummy silicon oxide layer 61 is formed as one body with the silicon oxide films 12. Thus, the semiconductor memory device 2 according to the embodiment is manufactured.

Effects of the embodiment will now be described.

In the embodiment, when forming the silicon oxide layer 34 in the process shown in FIG. 16, the portions are deposited to be thicker proximal to the slits 53. Therefore, as shown in FIG. 13, the silicon oxide layers 34 that surround the silicon pillars 20b positioned at the two Y-direction end portions of the stacked body 15 are thicker than the silicon oxide layers 34 surrounding the silicon pillars 20a positioned at the Y-direction central portion of the stacked body 15. As described above, the electric field that is applied from the electrode film 13 to the silicon pillar becomes weaker as the silicon oxide layer 34 is thicker.

Therefore, in the embodiment as shown in FIG. 13, the major diameters Db of the silicon pillars 20b positioned at the two Y-direction end portions of the stacked body 15 are set to be smaller than the major diameters Da of the silicon pillars 20a positioned at the Y-direction central portion. As described above, the electric field applied from the electrode film 13 to the silicon pillar becomes stronger as the major diameter of the silicon pillar 20 becomes small because the curvature of the surface of the electrode film 13 opposing the silicon pillar 20 becomes large.

Thereby, for the memory cell transistors MC positioned at the Y-direction central portion of the stacked body 15, the major diameter of the silicon pillar 20 is large; and the silicon oxide layer 34 is thin. On the other hand, for the memory cell transistors MC positioned at the two Y-direction end portions of the stacked body 15, the major diameter of the silicon pillar 20 is small; and the silicon oxide layer 34 is thick.

As a result, according to the embodiment as well, similarly to the first embodiment described above, the effects due to the major diameter of the silicon pillar 20 can cancel the effects due to the thickness of the silicon oxide layer 34. Therefore, the fluctuation of the threshold of the program operation is small; and the number of repetitions of the application of the programming potential and the verification can be reduced. As a result, the operation speed of the semiconductor memory device 2 is high.

Otherwise, the configuration, the manufacturing method, the operations, and the effects of the embodiment are similar to those of the first embodiment described above.

### Modification of Second Embodiment

A modification of the second embodiment will now be described.

FIG. 17 is a cross-sectional view showing a semiconductor memory device according to the modification.

As shown in FIG. 17, similarly to the semiconductor memory device 1b according to the second modification of the first embodiment described above (referring to FIG. 8), nine columns of the silicon pillars 20 are arranged along the Y-direction in the stacked body 15 in the semiconductor memory device 2a according to the modification. Each of the columns of the silicon pillars 20 extends in the X-direction.

Also, in the modification, contrary to the device 1b, the silicon oxide layer 34 is thick and the major diameter is small when viewed from the Z-direction for the silicon pillars 20 more proximal to the source electrode plate 17. In other words, as shown in FIG. 17, when focusing on the five silicon pillars 20c, 20d, 20e, 20f, and 20g from the Y-direction central column toward the column at the Y-direction end portion of the stacked body 15, if Lc>Ld>Le>Lf>Lg, then Dc>Dd>De>Df>Dg, and tc<td<te<tf<tg, where the distances between the silicon pillars 20 and the source electrode plate 17 proximal to each silicon pillar 20 respectively are Lc, Ld, Le, Lf, and Lg; the major diameters when viewed from the Z-direction respectively are Dc, Dd, De, Df, and Dg; and the thicknesses of the silicon oxide layers 34 surrounding the silicon pillars 20 respectively are tc, td, te, tf, and tg.

According to the modification, even in the case where the nine columns of the silicon pillars 20 are arranged in the stacked body 15, effects similar to those of the second embodiment described above can be obtained.

Otherwise, the configuration, the manufacturing method, the operations, and the effects of the modification are similar to those of the second embodiment described above.

The silicon pillars 20c that belong to the Y-direction central column may be dummy pillars. In such a case, the shape and major diameter of the silicon pillars 20c may not satisfy the relationship described above.

In the second embodiment as well, similarly to the first modification (referring to FIG. 7), the fourth modification (referring to FIG. 10), and the fifth modification (referring to FIG. 11) of the first embodiment described above, the cross-sectional shape may be an ellipse for some or all of the silicon pillars 20. However, in such a case, contrary to the modifications of the first embodiment, the major diameter is set to be larger for the silicon pillars 20 disposed at the center of the stacked body 15, that is, for the silicon pillars 20 more distal to the source electrode plate 17.

### Third Embodiment

A third embodiment will now be described.

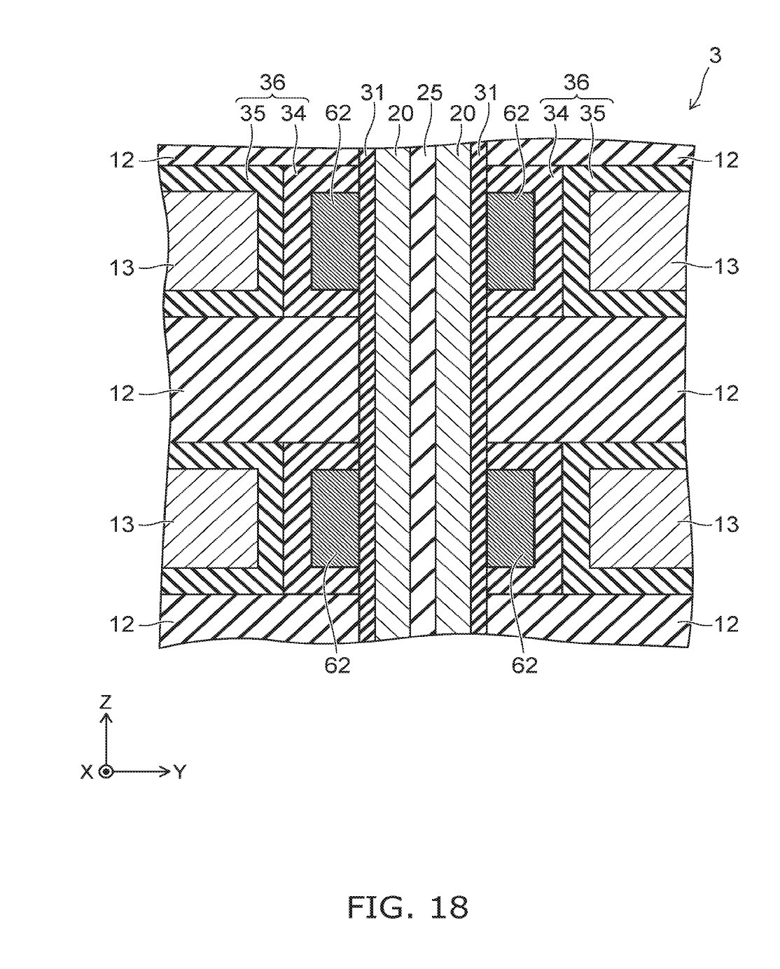

FIG. 18 is a cross-sectional view showing a semiconductor memory device according to the embodiment.

As shown in FIG. 18, the semiconductor memory device 3 according to the embodiment differs from the semiconductor memory device 1 according to the first embodiment described above (referring to FIG. 2) in that a floating gate electrode 62 is provided instead of the charge storage film 32. The floating gate electrode 62 is formed of a conductive material and is formed of, for example, polysilicon. Also, the floating gate electrode 62 is divided every crossing portion between the silicon pillars 20 and the electrode films 13. In other words, one floating gate electrode 62 belongs to one memory cell transistor MC. Also, the silicon oxide layer 34 is provided to cover the upper surface of the floating gate electrode 62, the lower surface of the floating gate electrode 62, and the side surface of the floating gate electrode 62 on the electrode film 13 side.

According to the embodiment, the electrons can be stored at a higher density by using the floating gate electrode 62 made of the conductive material as the charge storage member. As a result, even higher integration of the semiconductor memory device is possible. Also, by dividing the floating gate electrode 62 every memory cell transistor MC, the movement of the electrons between the memory cell transistors MC can be suppressed even when the integration of the memory cell transistors MC is increased; and degradation of the data retention characteristics can be suppressed.

Otherwise, the configuration, the operations, and the effects of the embodiment are similar to those of the first embodiment described above.

### Fourth Embodiment

A fourth embodiment will now be described.

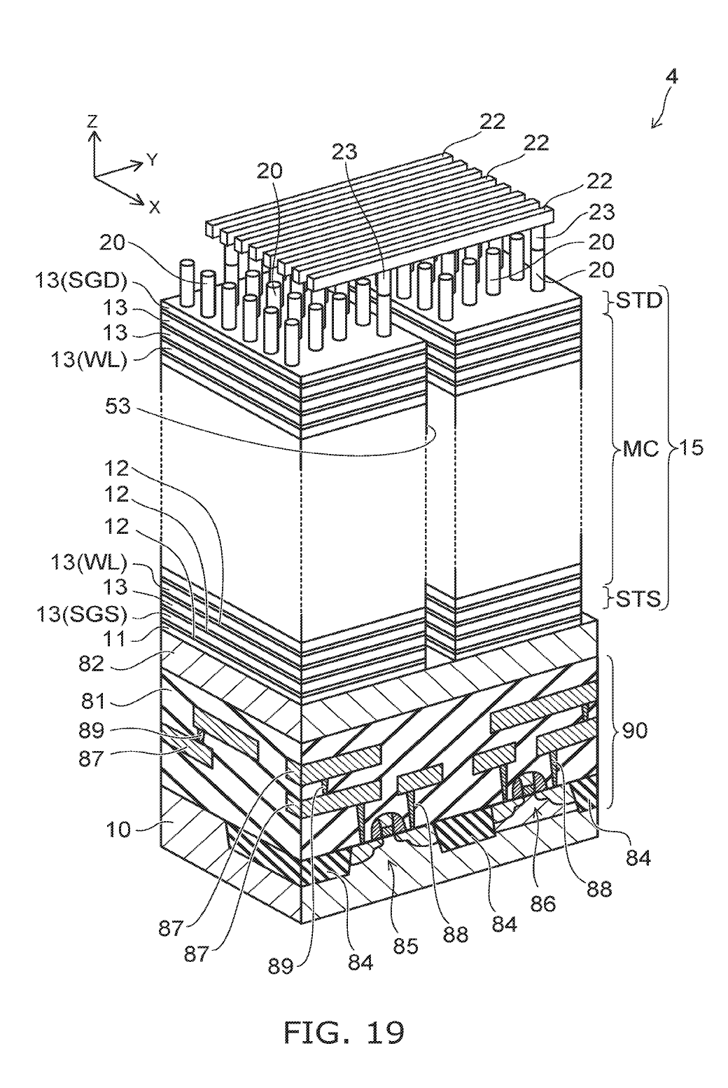

FIG. 19 is a perspective view showing a semiconductor memory device according to the embodiment.

As shown in FIG. 19, in the semiconductor memory device 4 according to the embodiment, an under-cell circuit 90 is provided below the memory cell array in addition to the configuration of the semiconductor memory device 1 according to the first embodiment described above (referring to FIG. 1).

A specific description is as follows.

In the semiconductor memory device 4, an inter-layer insulating film 81 and a source electrode film 82 are provided between the silicon substrate 10 and the stacked body 15. The inter-layer insulating film 81 is formed of, for example, silicon oxide; and the source electrode film 82 is formed of, for example, polysilicon to which an impurity is added. The silicon pillar 20 is connected not to the silicon substrate 10 but to the source electrode film 82. The source electrode film 82 is separated from the silicon substrate 10 by the inter-layer insulating film 81. Also, the source electrode film 82 is provided to be connected commonly to the multiple stacked bodies and is further connected to, for example, a source line (not illustrated) of a lower layer.

Also, the under-cell circuit 90 is formed inside the inter-layer insulating film 81 and the upper layer portion of the silicon substrate 10. The under-cell circuit 90 is a portion of the drive circuit that performs the programming, reading, and erasing of data to and from the memory cell transistors MC and includes, for example, sense amplifiers.

For example, the upper layer portion of the silicon substrate 10 is partitioned into multiple active areas by STI (Shallow Trench Isolation) 84; an n-type MOSFET (Metal Oxide-Semiconductor Field-Effect Transistor) 85 is formed in one active area; and a p-type MOSFET 86 is formed in another active area. Also, multiple levels of interconnects 87 are provided inside the inter-layer insulating film 81; contacts 88 that connect the interconnects 87 to the silicon substrate 10 are provided; and vias 89 that connect the interconnects 87 to each other are provided. The depictions of the n-type MOSFET 85, the p-type MOSFET 86, the interconnects 87, etc., in FIG. 19 are schematic and do not necessarily match the sizes and arrangement of the actual elements.

Also, the source electrode plate 17 described in reference to FIG. 1 is not provided inside the slit 53 of the semiconductor memory device 4; and the source line 21 that is connected to the upper end of the source electrode plate 17 also is not provided. For example, an insulating body (not illustrated) such as the insulating plate 18 (referring to FIG. 3) is filled into the slit 53. The potential that is necessary for driving is supplied from the under-cell circuit 90 to the source electrode film 82.

According to the embodiment, the space between the silicon substrate 10 and the stacked body 15 can be utilized effectively; therefore, the surface area of the circuit disposed at the periphery of the stacked body 15 can be reduced by this amount. Also, the source electrode plate 17 and the source line 21 can be omitted. As a result, the integration of the semiconductor memory device 4 is high. Otherwise, the configuration, the manufacturing method, and the effects of the embodiment are similar to those of the first embodiment described above.

In the third and fourth embodiments described above, the configurations of the silicon pillar 20 and the silicon oxide layer 34 may be as in the second embodiment.

According to the embodiments described above, a semiconductor memory device can be realized in which the operation speed is high.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor memory device, comprising:
a stacked body including an electrode film and an insulating film arranged alternately along a first direction;
a first semiconductor member extending in the first direction and piercing the electrode film and the insulating film;
a first charge storage layer provided at a periphery of the first semiconductor member;
a first insulating layer contacting the insulating film and being provided at a periphery of the first charge storage layer;
a second semiconductor member extending in the first direction and piercing the electrode film and the insulating film;
a second charge storage layer provided at a periphery of the second semiconductor member; and
a second insulating layer contacting the insulating film and being provided at a periphery of the second charge storage layer,
the first insulating layer being thicker than the second insulating layer,
a major diameter of the first semiconductor member being smaller than a major diameter of the second semiconductor member when viewed from the first direction.

2. The device according to claim 1, further comprising two electrode plates arranged along a second direction crossing the first direction, the stacked body being interposed between the two electrode plates,
a first distance between the first semiconductor member and the electrode plate proximal to the first semiconductor member being longer than a second distance between the second semiconductor member and the electrode plate proximal to the second semiconductor member.

3. The device according to claim 2, wherein configurations of the first insulating layer and the second insulating layer are tubular configurations extending in the first direction.

4. The device according to claim 1, further comprising two electrode plates arranged along a second direction crossing the first direction, the stacked body being interposed between the two electrode plates,
a first distance between the first semiconductor member and the electrode plate proximal to the first semiconductor member being shorter than a second distance between the second semiconductor member and the electrode plate proximal to the second semiconductor member.

5. The device according to claim 4, wherein the first insulating layer and the second insulating layer are disposed also on two first-direction sides when viewed from the electrode film.

6. The device according to claim 1, further comprising:
a third semiconductor member extending in the first direction and piercing the electrode film;
a third charge storage layer provided at a periphery of the third semiconductor member; and
a third insulating layer contacting the insulating film and being provided at a periphery of the third charge storage layer, the second insulating layer being thicker than the third insulating layer,
a major diameter of the second semiconductor member being smaller than a major diameter of the third semiconductor member when viewed from the first direction.

7. The device according to claim 6, further comprising two electrode plates arranged along a second direction crossing the first direction, the stacked body being interposed between the two electrode plates,
a first distance between the first semiconductor member and the electrode plate proximal to the first semiconductor member being longer than a second distance between the second semiconductor member and the electrode plate proximal to the second semiconductor member, the second distance being longer than a third distance between the third semiconductor member and the electrode plate proximal to the third semiconductor member.

8. The device according to claim 6, further comprising two electrode plates arranged along a second direction crossing the first direction, the stacked body being interposed between the two electrode plates,
a first distance between the first semiconductor member and the electrode plate proximal to the first semiconductor member being shorter than a second distance between the second semiconductor member and the electrode plate proximal to the second semiconductor member, the second distance being shorter than a third distance between the third semiconductor member and the electrode plate proximal to the third semiconductor member.

9. The device according to claim 1, wherein the first insulating layer and the second insulating layer include silicon and oxygen.

10. The device according to claim 1, wherein the first charge storage layer and the second charge storage layer include silicon and nitrogen.

11. The device according to claim 1, further comprising:
a third insulating layer provided between the first semiconductor member and the first charge storage layer; and
a fourth insulating layer provided between the second semiconductor member and the second charge storage layer.

12. The device according to claim 1, further comprising:
a third insulating layer provided between the first insulating layer and the electrode film, a composition of the third insulating layer being different from a composition of the first insulating layer; and
a fourth insulating layer provided between the second insulating layer and the electrode film, a composition of the fourth insulating layer being different from a composition of the second insulating layer.

13. The device according to claim 12, wherein
a dielectric constant of the third insulating layer is higher than a dielectric constant of the first insulating layer, and
a dielectric constant of the fourth insulating layer is higher than a dielectric constant of the second insulating layer.

14. The device according to claim 12, wherein the third insulating layer and the fourth insulating layer include aluminum and oxygen.

15. The device according to claim 1, further comprising:
two electrode plates arranged along a second direction crossing the first direction, the stacked body being interposed between the two electrode plates;
a third semiconductor member extending in the first direction and piercing the electrode film and the insulating film; and
a fourth semiconductor member extending in the first direction and piercing the electrode film and the insulating film,
the first semiconductor member, the second semiconductor member, the third semiconductor member, and the fourth semiconductor member having mutually-different positions in the second direction.

16. The device according to claim 15, further comprising:
a fifth semiconductor member extending in the first direction and piercing the electrode film and the insulating film;
a sixth semiconductor member extending in the first direction and piercing the electrode film and the insulating film;
a seventh semiconductor member extending in the first direction and piercing the electrode film and the insulating film;
an eighth semiconductor member extending in the first direction and piercing the electrode film and the insulating film; and
a ninth semiconductor member extending in the first direction and piercing the electrode film and the insulating film,
the first semiconductor member, the second semiconductor member, the third semiconductor member, the fourth semiconductor member, the fifth semiconductor member, the sixth semiconductor member, the seventh semiconductor member, the eighth semiconductor member, and the ninth semiconductor member having mutually-different positions in the second direction.

17. The device according to claim 1, wherein a shape of the first semiconductor member is a circle when viewed from the first direction, and a shape of the second semiconductor member is an ellipse when viewed from the first direction.

18. The device according to claim 1, wherein shapes of the first semiconductor member and the second semiconductor member are ellipses when viewed from the first direction, and an eccentricity of the first semiconductor member is smaller than an eccentricity of the second semiconductor member.
